(19) United States
(12) Patent Application Publication
(10) Pub. No.: US 2005/0093014 A1
(43) Pub. Date: May 5, 2005

(54) Solid state light-emitting element, method for producing the element, and projector

(75) Inventors: Hideya Seki, Okaya-shi (JP); Takashi Takeda, Suwa-shi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 10/941,905

(22) Filed: Sep. 16, 2004

(30) Foreign Application Priority Data
Sep. 25, 2003 (JP) 2003-333359

(51) Int. Cl. H01L 29/24

(52) U.S. Cl. 257/100

(57) ABSTRACT

Aspects of the invention can provide a solid state light-emitting element having a solid state light-emitting element chip that emits light in electric current injection, and electrodes for injecting electric current into the solid state light-emitting element chip, the electrodes being disposed on an ejection face of the solid state light-emitting element chip. An optical-path change device, which visually masks electrode forming areas in which the electrodes are formed, can be provided on the ejection face of the solid state light-emitting element chip. Accordingly, irregularity in a projection image due to electrode forming areas can be prevented.

### BACKGROUND OF THE INVENTION

1. Field of Invention

Aspects of the invention can relate to a solid state light-emitting element, method for producing the element, and projector.

2. Description of Related Art

In related projectors, light sources, such as a halogen lamp and, more recently, a high pressure mercury lamp (UHP) have been mostly used as the light source. A light source using the UHP that is an electric-discharge type lamp has required a high-tension power circuit, and has been large and heavy, therefore obstructed to achieve a smaller and lighter projector. Moreover, the life of the UHP has been still short though it is longer than that of the halogen lamp, in addition, control of the light source (fast lighting, lighting-out, or modulation) has been substantially impossible, and a long time of several minutes has been required for building up.

Thus, recently, an LED light emitter has been considered as a new light source. LED is ultra-small, ultra-lightweight, and has long life. Moreover, the lighting and lighting-out, or ejected light level can be freely adjusted by controlling drive current. In this regard, the LED is promising even for a light source of the projector, and development on use for a small-and-portable projector with a small screen has been started, see, for example, JP-A-2000-112031.

Here, a related light-emitting element 100 using the LED is described with reference to FIG. 12 and FIG. 13. FIG. 12 is a schematic structure view of a red light-emitting element 100R, where (a) is a cross sectional view, and (b) is a top view of a chip 110. FIG. 13 is a schematic structure view of green and blue light-emitting elements 100GB, where (a) is a cross sectional view, and (b) is a top view of a chip 160.

As shown in FIG. 12, the red light-emitting element 100R has the chip 110 that emits light in electric current injection, a radial electrode 120 placed on an ejection face of the chip 110, and a counter electrode 140 disposed oppositely to the electrode 120 across the chip 110. The electrode 120 is bound with a bonding wire 130 by solder 150. Such a red light-emitting element 100R emits the light in the electric current injection from the electrode 120 via the bonding wire 130.

Also, as shown in FIG. 13, the green and blue light-emitting elements 100GB have a chip 160 that emits the light in the electric current injection, a transparent electrode 170 disposed on an ejection face of the chip 160, and electrodes 180 placed on bottoms (electrode formation areas) of a plurality of grooves 160a formed parallel in a way of scraping a light-emitting layer of the chip 160. Such green and blue light-emitting elements 100GB emit the light in the electric current injection from the electrodes 180.

### SUMMARY OF THE INVENTION

However, particularly, when such a red light-emitting element 100R is used for the light source of the projector, shadows of the electrode 120 and the solder 150 are projected on a screen. Also, when the green and blue light-emitting elements 100GB are used for the light source of the projector, shadows of the grooves 160a are produced on the screen, because the emitting layer does not exist on the grooves 160a.

Therefore, in the related projector, illuminance of the light emitted from the light source can be made uniform by a rod lens or the like before the light is projected on the screen. However, a problem of increase in projector size occurs, since a long rod lens is necessary for making the light emitted from the described red light-emitting element 100R and the like to be uniform.

Aspects of the invention can prevent irregularity in a projection image due to the electrode formation areas.

To achieve the above object, the solid state light-emitting element according to the invention having a solid state light-emitting element chip that emits the light in the electric current injection, and electrodes for injecting the electric current into the solid state light-emitting element chip, the electrodes being disposed on the ejection face of the solid state light-emitting element chip, can include, on the ejection face of the solid state light-emitting element chip, an optical-path change device that visually masks the electrode formation areas in which the electrodes are formed.

According to the solid state light-emitting element according to the invention having such characteristics, the optical-path change device that visually masks the electrode formation areas is provided on the ejection face of the solid state light-emitting element chip. Therefore, the irregularity in the projection image, which is produced when emission light radiated from the solid state light-emitting element is projected, due to the electrode formation areas can be prevented.

The optical path of the emission light is changed by the optical-path change device in this way, resulting in a condition that the illuminance of the emission light is made uniform in some degree. Therefore, when the solid state light-emitting element according to the invention is used for the light source of the projector, the long rod lens, which must be provided in the related projector, may be shortened, and a smaller and lighter projector can be achieved.

Moreover, the optical-path change device may employ a configuration that the optical path is changed by refraction or reflection. In this way, by using the refraction or reflection of light, the optical path of the emission light can be easily changed such that the electrode formation areas are masked.

Specifically, the optical-path change device can be formed using a translucent material having roots corresponding to the electrode formation areas, thereby the optical path of the emission light can be changed using refraction. In this way, the optical-path change device can be formed using the translucent material having roots corresponding to the electrode formation areas, thereby an optical path of obliquely-ejected emission light is changed (refracted) vertically to the ejection face of the solid state light-emitting element chip above the electrode formation areas, therefore the electric formation areas can be visually masked. Resin can be used for the translucent material.

When the optical path is changed using reflection, a configuration that the optical-path device can be made as reflection mirrors formed on the electrodes can be employed. In this way, the optical-path change means is made as the reflection mirrors formed on the electrodes, thereby the optical path of the obliquely-ejected emission light is changed (reflected) vertically to the ejection face of the solid state light-emitting element chip above the electrode formation areas, therefore the electrode formation areas can be visually masked.

The reflection mirrors are integrally formed with the electrodes using a same material, thereby the optical-path change means can be easily formed.

Consequently, according to the exemplary projector characterized by having the solid state light-emitting element according to the invention as the light source, the irregularity in the projection image due to the electrode formation areas can be prevented. Moreover, since the rod lens can be shortened by having the solid state light-emitting element according to the invention as the light source, the smaller and lighter projector can be provided.

Next, an exemplary method for producing the solid state light-emitting element according to the invention, the element having the solid state light-emitting chip that emits the light in the electric current injection, and the electrodes for injecting the electric current into the solid state light-emitting element chip, the electrodes being disposed on the ejection face of the solid state light-emitting element chip. The method can include a step for making the electrode formation areas, in which the electrodes are formed, to be liquid-repellent, a step for placing liquid resin on the ejection face of the solid state light-emitting element chip, and a step for hardening the liquid resin.

According to the method for producing the solid state light-emitting element according to the invention having such characteristics, the electrode formation areas are subjected to a liquid-repellent treatment, and then the liquid resin is placed on the ejection face of the solid state light-emitting element chip. Accordingly, the liquid resin is repelled on the electrode formation areas, and the roots corresponding to the electrode formation areas can be formed in the liquid resin. Then, the liquid resin is hardened, thereby the optical-path change device having the roots corresponding to the electrode formation areas can be formed. Consequently, according to the solid state light-emitting element produced by the method for producing the solid state light-emitting element according to the invention, the electrode formation areas can be visually masked.

Moreover, the liquid resin can be placed by a droplet discharge technique, thereby liquid resin having a desired profile can be easily placed. Accordingly, the roots corresponding to the electrode formation areas can be easily formed in the liquid resin.

As a method for hardening the liquid resin, a method where thermosetting resin is used as the liquid resin and baked after placement can be used. A method where photo-curing resin is used as the liquid resin and subjected to light irradiation after placement can be also used. When the photo-curing resin is used in this way, it is also possible that the electric current is injected into the solid state light-emitting element chip to make the chip emit the light, and the liquid resin is hardened using the emission light.

### BRIEF DESCRIPTION OF THE DRAWINGS

The invention will be described with reference to the accompanying drawings, wherein like numerals reference like elements, and wherein:

FIG. 1 is a schematic view showing a general configuration of a projector according to an exemplary embodiment;

FIG. 2 is a schematic structure view of the light source apparatus 10;

FIG. 3 is a schematic structure view of the red light-emitting element 1R;

FIG. 4 is an expanded schematic view of the vicinity of the chip 12 in FIG. 3;

FIG. 5 is a view showing an aspect of optical-path change of emission light;

FIG. 6 is a schematic structure view of the green and blue light-emitting elements 1G, 1B;

FIG. 7 is an expanded schematic view of the vicinity of the chip 31 in FIG. 6;

FIG. 8 is a view showing an aspect of the optical-path change of the emission light;

FIG. 9 is a view showing an example of a method for producing the green and blue light-emitting elements 1G, 1B;

FIG. 10 is a schematic structure view of the red light-emitting element 41R according to the second exemplary embodiment;

FIG. 11 is a schematic structure view of the green and blue light-emitting elements 41G, 41B according to the second exemplary embodiment;

FIG. 12 is a schematic structure view of the related red light-emitting element 100R; and

FIG. 13 is a schematic structure view of the related green-and-blue light-emitting element 100GB.

### DETAILED DESCRIPTION OF PREFERRED EMBODIMENTS

Hereinafter, an exemplary embodiment of the solid state light-emitting element, method for producing the element, and projector according to the invention is described with reference to drawings.

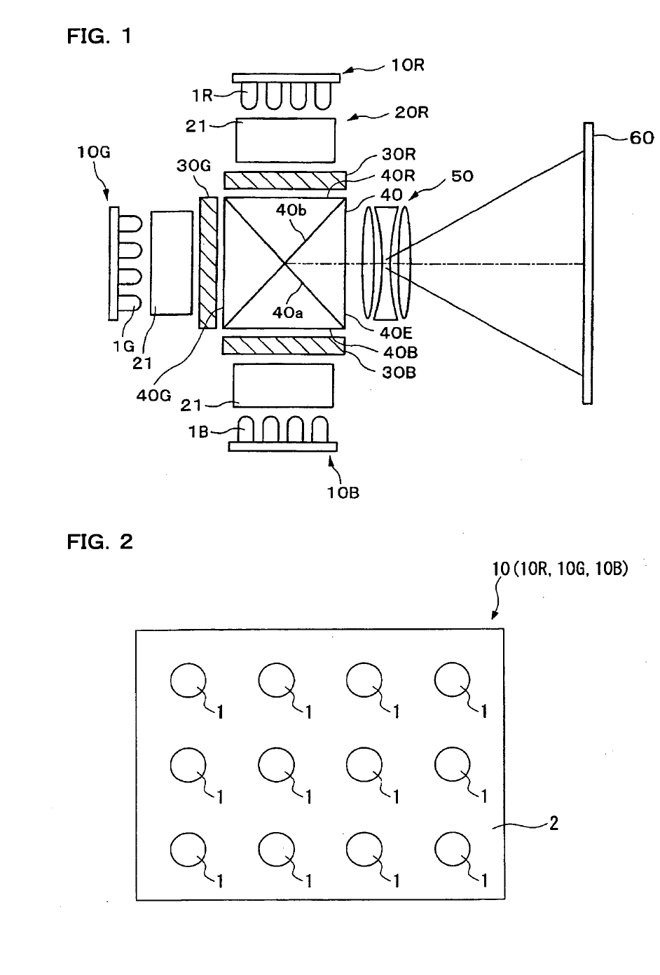

FIG. 1 is a schematic view showing a general configuration of a projector according to the exemplary embodiment. In all drawings below, for better viewing of the drawings, thickness or a dimension ratio of each component is made appropriately different.

As shown in FIG. 1, the projector of the exemplary embodiment is a 3-plate liquid crystal projector, wherein liquid crystal devices 30R, 30G, 30B as a light modulating device are placed on three light injection faces 40R, 40G, 40B of a dichroic cross prism 40 as color composition means in an opposite manner respectively, and light source devices 10R, 10G, 10B that can eject color light of R (red), G (green), and B (blue) are placed on back sides (opposite sides to the cross dichroic prism 40) of respective liquid crystal devices 30R, 30G, and 30B, respectively.

As shown in FIG. 2, the light source device 10 (10R, 10G, 10B) has a plurality of light-emitting elements 1 emitting same color light, and a substrate 2 having one side on which the light-emitting elements 1 are placed. Each of the light emitting elements 1, which includes, for example, a light-emitting diode (LED), and is lighted by a lighting control circuit (not shown).

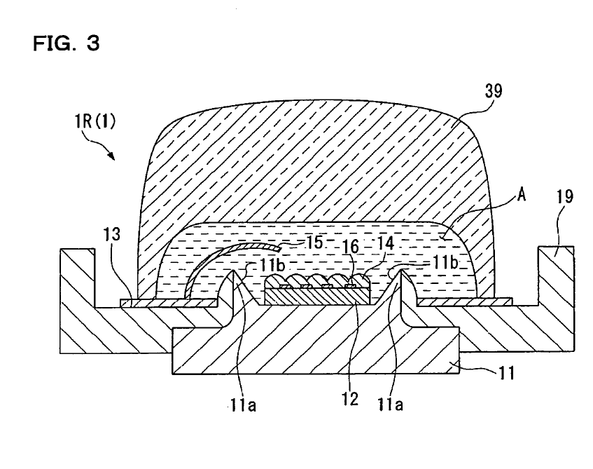

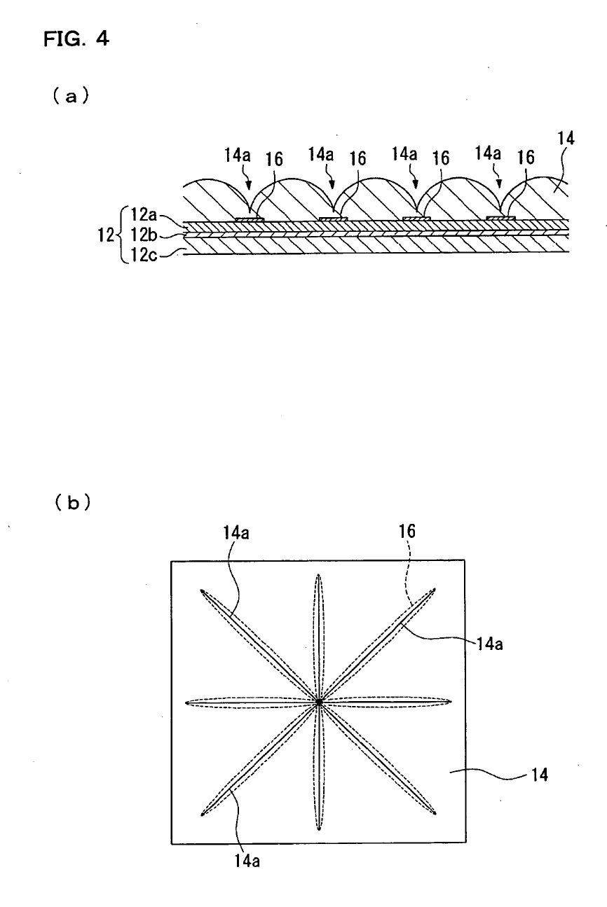

FIG. 3 is a schematic structure view of the red light-emitting element IR. As shown in the figure, the red light-emitting element 1R is a bipolar element, and as shown in the figure, a chip 12 (solid state light-emitting element chip) in which a p-layer 12a, light-emitting layer 12b, and n-layer 12c (refer to FIG. 4) are sequentially stacked is mounted on an upside of a heat transfer part 11 including a metal material. Electrodes 16 are placed on a top of the chip 12, and an optical-path change lens (optical-path change means) 14 is mounted on an upside of the electrodes 16. A bonding wire 15 is led out from the electrodes 16 in order to connect the electrodes 16 to a lead frame 13 as an outer connecting terminal. Moreover, the heat transfer part 11 acts to radiate calorie generated in the chip 12 to the outside, and is used as a counter electrode of the electrodes 16. The solid state light-emitting element according to the invention can include the chip 12, electrodes 16, and heat transfer part 11 in the exemplary embodiment.

FIG. 4 is an enlarged schematic view of the vicinity of the chip 12, where (a) is a cross sectional view, and (b) is a top view. As shown in the figure, the electrodes 16 are formed radially on the top (ejection face) of the chip 12. The optical-path change lens 14 having roots 14a corresponding to areas for forming the electrodes 16 is placed on the upsides of the chip 12 and electrodes 16. The optical-path change lens 14 is formed using the transparent material, such as resin.

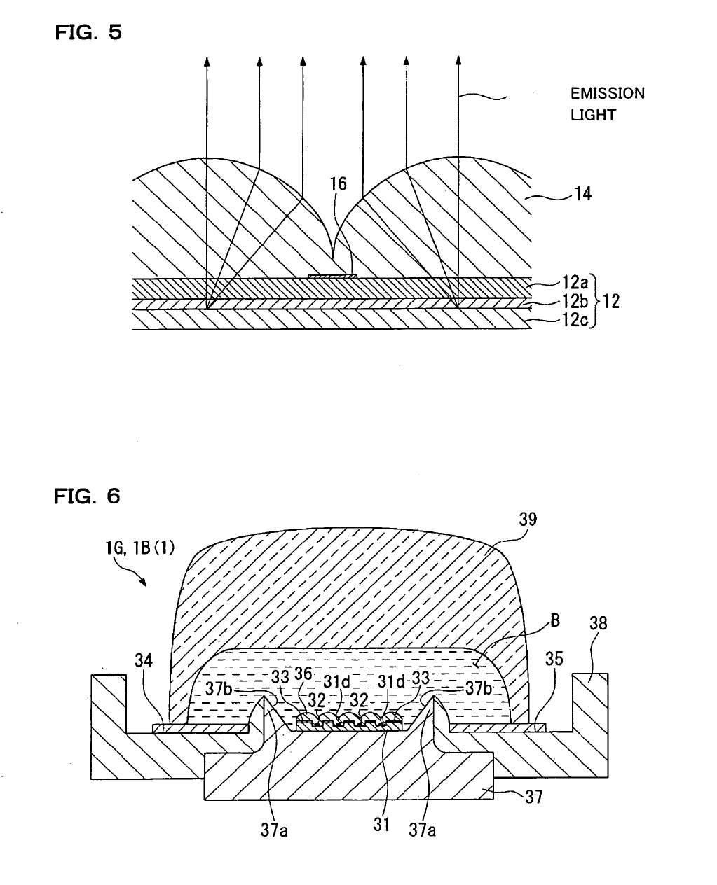

When the electric current is injected into such a chip 12 and the chip 12 emits the light, as shown in FIG. 5, the obliquely-ejected emission light refracts when it is ejected from the optical-path change lens 14, and becomes vertical to the ejecting face of the chip 12 above the electrodes 16. Consequently, the emission light is ejected via such an optical-path change lens 14, thereby the illuminance of the emission light is made uniform, and the electrodes 16 can be visually masked. In FIG. 4 and FIG. 5, while not shown, the bonding wire 15 is connected to the electrodes 16 penetratingly through the optical-path change lens 14.

Referring again to FIG. 3, a wall part 1 a is provided at a position surrounding a mounting face of the chip 12 (connecting face of the chip 12 to the heat transfer part 11) on the heat transfer part 11. The wall part 11a has a tapered shape in which an end side is thinner than an anchor side, and a side face 11b of the part opposed to the chip 12 is a slope that inclines outwardly from the chip 12. A light reflection face including a film or powder of a metal having high reflectance, such as aluminum or silver is formed on the slope 11b, so that light isotropically ejected from the chip 12 is reflected in a substantially vertical direction to the mounting face and thus responsible for illumination.

The heat transfer part 11 and lead frame 13 are integrally formed with a resin frame 19, and a lens body 39 is provided on the resin frame 19 in a way of enveloping the chip 12 and the bonding wire 15. A fluid A having high heat conductivity, such as silicon-gel, is filled between the lens body 39 and the frame 19 in order to further improve heat radiation efficiency.

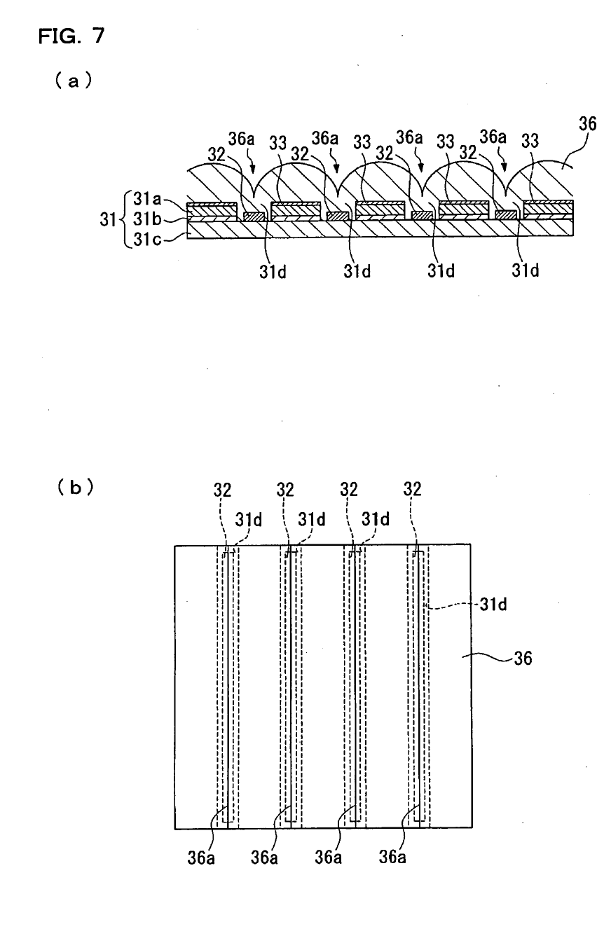

FIG. 6 is a schematic structure view of the green and blue light-emitting elements 1G, 1B. As shown in the figure, the green and blue light-emitting elements 1G, 1B are bipolar elements, and a chip 31 (solid state light-emitting element chip) in which a p-layer 31a, light-emitting layer 31b, and n-layer 31c (refer to FIG. 7) are sequentially stacked is mounted on an upside of a heat transfer part 37 including a metal material. A plurality of grooves 31d (electrode formation areas) are formed parallel on the chip 31 in a way of scraping the light emitting layer 31b (refer to FIG. 7), and electrodes 32 directly contacting to the n-layer 31c (refer to FIG. 7) of the chip 31 are placed on bottoms of the grooves 31d. Transparent electrodes 33 are placed on the p-layer 31a of the chip 31. These electrodes 32 and transparent electrodes 33 are electrically connected to lead frames 34, 35 as outer connecting terminals through lead wires (not shown) that do not shadow an ejection face of the chip 31, respectively. An optical-path change lens (optical-path change means) 36 is mounted on an upside of the chip 31.

FIG. 7 is an enlarged schematic view of the vicinity of the chip 31, where (a) is a cross sectional view, and (b) is a top view. As shown in the figure, the electrodes 32 are formed on the bottoms of the grooves 31d extendedly in a longitudinal direction of the grooves 31d. The optical-path change lens 36 having roots 36a corresponding to the grooves 31d is placed on the upside of the chip 31. The optical-path change lens 36 is formed using the transparent material, such as resin.

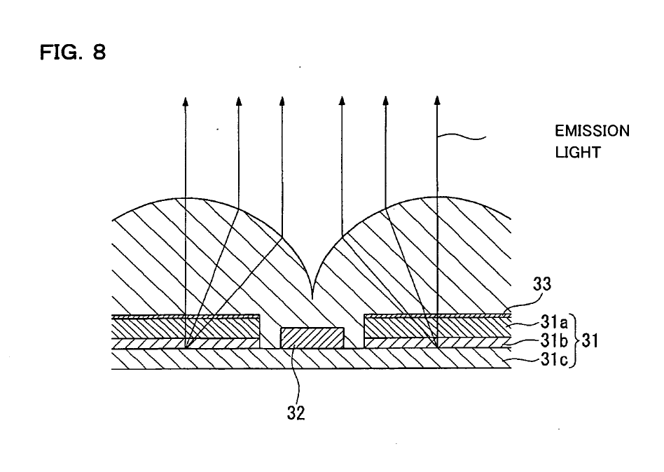

When the electric current is injected into such a chip 31, and the chip 31 emits light, as shown in FIG. 8, the obliquely-ejected emission light refracts when it is ejected from the optical-path change lens 36, and becomes vertical to the ejection face of the chip 31 above the grooves 31d. Consequently, the emission light is ejected via such an optical-path change lens 36, thereby the illuminance of the emission light is made uniform, and the grooves 31d can be visually masked.

With reference again to FIG. 6, a wall part 37a is provided at a position surrounding a mounting face of the chip 31 (connecting face between the chip 31 and the heat transfer part 37) on the heat transfer part 37, as in the heat transfer part 11 of the red light-emitting element IR. The wall part 37a has a tapered shape in which an end side is thinner than an anchor side, and a side face 37b of the part opposed to the chip 31 is a slope that inclines outwardly from the chip 31. A light reflection face comprising the film or powder of the metal having the high reflectance such as aluminum or silver is formed on the slope 37b, so that light isotropically ejected from the chip 31 is reflected in a substantially vertical direction to the mounting face and responsible for illumination.

The heat transfer part 37 and lead frames 34, 35 are integrally formed with a resin frame 38, and a lens body 39 is provided on the resin frame 38 in a way of enveloping the chip 31. A fluid B having the high heat conductivity such as silicon-jell is filled between the lens body 39 and the frame 38 in order to further improve the heat radiation efficiency.

With reference to FIG. 1, rod lenses 21 are placed between respective light source devices 10R, 10G, 10B and the corresponding liquid crystal devices 30R, 30G, 30B, as a device for making illuminance uniform for making illuminance distribution of the emission light to be uniform in the liquid crystal devices 30R, 30G, 30B. The rod lenses 21 make the illuminance of the emission light to be uniform by making multiple reflection of the emission light occur in that rod lenses 21. As described above, since the illuminance of the emission light has been made uniform in some degree by the optical-path change lenses 14, 36, the rod lenses 21 are shorter than rod lenses provided in a conventional projector. Consequently, the projector can be made smaller and lighter.

The dichroic cross prism 40 has a structure in which four rectangular prisms are stuck with each together, and light reflection films (omitted to be shown) comprising a dielectric multilayer film is formed crosswise on the stuck faces 40a, 40b. Specifically, a light reflection film, which reflects red image light produced in the liquid crystal device 30R and transmits green and blue image light produced in the liquid crystal devices 30G, 30B respectively, is provided on the stuck face 40a; and a light reflection film, which reflects blue image light produced in the liquid crystal device 30B and transmits red and green image light produced in the liquid crystal devices 30R, 30G respectively, is provided on the stuck face 40b. Respective color image light optically guided to a light ejection face 40E of the dichroic cross prism 40 is projected on a screen 60 by a projection lens (ejection optics system) 50.

Here, illuminance of the emission light from the light emitting element 1 is made uniform in some degree by the optical-path change lenses 14, 36, and further made uniform by the rod lenses 21, therefore the irregularity of the projection image due to the electrode formation areas is prevented.

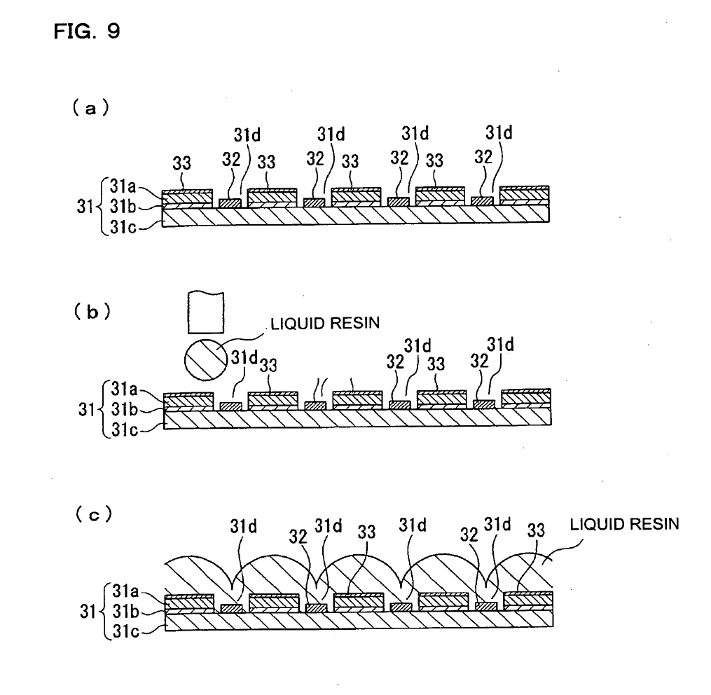

Next, a method for producing the solid state light-emitting element according to the invention is described with reference to FIG. 9, using a method for producing green and blue light-emitting elements 1G, 1B having the optical-path change lens 36 as an example.

First, as shown in FIG. 9(a), the chip 31 is prepared, on which the electrodes 32 and the transparent electrodes 33 are placed, and the bottoms of the grooves 31d formed on the chip 31 are subjected to the liquid-repellent treatment. As a method of the liquid-repellent treatment, for example, a method of coating tetrafluoroethylene resin or the like on the bottoms of the grooves 31d is given.

Subsequently, as shown in FIG. 9(b), photo-curing liquid resin can be discharged and placed on the top of the chip 31 in which the bottoms of the grooves 31d has been subjected to the liquid-repellent treatment, by the droplet discharge technique using, for example, inkjet apparatus, a dispenser or the like. In this way, the liquid resin is discharged and placed using the droplet discharge technique, thereby discharge level and a discharge position of the liquid resin can be finely adjusted, therefore a profile of the placed liquid resin can be easily controlled.

The liquid resin discharged by the droplet discharge technique in such a manner is repelled on the bottoms of the grooves 31d, since the bottoms of the grooves 31d has been subjected to the liquid-repellent treatment. Consequently, a predetermined amount of liquid resin can be discharged on the upside of the chip 31, thereby the liquid resin having roots corresponding to the grooves 31d as shown in FIG. 9(c) is placed on the chip 31. At ends of the chip 31, it is preferable that a predetermined form is placed to prevent the liquid resin from flowing outside the chip 31.

Subsequently, for example, electric current can be injected into the chip 31 to make the chip 31 emit light, and the liquid resin is hardened using the emission light. Thus, the optical-path change lens 36 is formed. Then, the lens body 39 filled with the fluid B is placed in a manner of covering the chip 31 and the optical-path change lens 36, thereby the green and blue light-emitting elements 1G, 1B are produced.

In the red light-emitting element IR, the tops of the electrodes 16 are subjected to the liquid-repellent treatment, and then the liquid resin is discharged and placed on the top of the chip 12, and then the liquid resin is hardened, thereby the optical-path change lens 14 is formed. However, in the red light-emitting element IR, the electrodes 16 needs to be connected to the bonding wire 15, as described above. Since the electrodes 16 are generally bound with the bonding wire 15 by the solder, it is preferable that the electrodes 16 are connected to the bonding wire 15 before the optical-path change lens 14 is formed, and then the liquid resin is discharged and placed avoiding the bonding wire 15. Even if the liquid resin is discharged and placed avoiding the bonding wire 15 in such a manner, the liquid resin can be easily discharged and placed by using the inkjet apparatus or the like.

When the thermosetting liquid resin used as the liquid resin, the resin is hardened by baking the liquid resin instead of the described hardening of the liquid resin using the light emitted from the chip.

Without such production steps, liquid resin that has been hardened in some degree is placed on the chip, and the liquid resin is pressed by a press having protrusions corresponding to the electrode formation areas, and then the liquid resin is hardened, thereby the optical-path change lens 36 can be also formed.

In the embodiment, since the LED is shown in a configuration where emission light is ejected from an electrode 16 side, a configuration where the optical-path change lens 14 is provided on the electrode 16 side is given. However, as another configuration, there is LED in a configuration where the light-emitting layer is grown on a transparent substrate, such as sapphire, then turned out and mounted, and emission light is ejected from a substrate side. That is, in such LED, a light-emitting layer side functions as the heat transfer part 37, and the substrate side is a top. Even in the LED in such a configuration, substantially same effects as in the solid state light-emitting element according to the embodiment can be achieved by similarly forming the optical-path change lens 14 at an ejection face side (face at the substrate side).

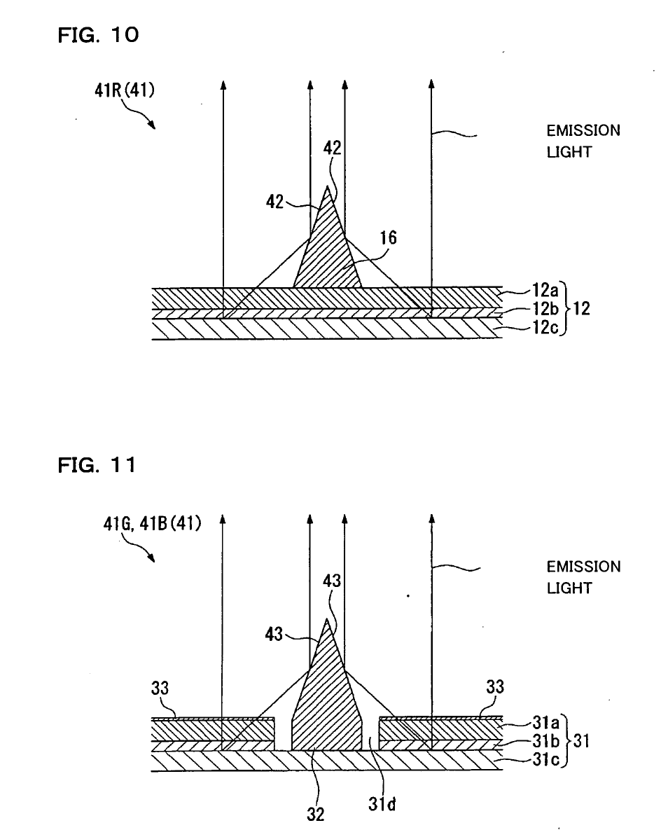

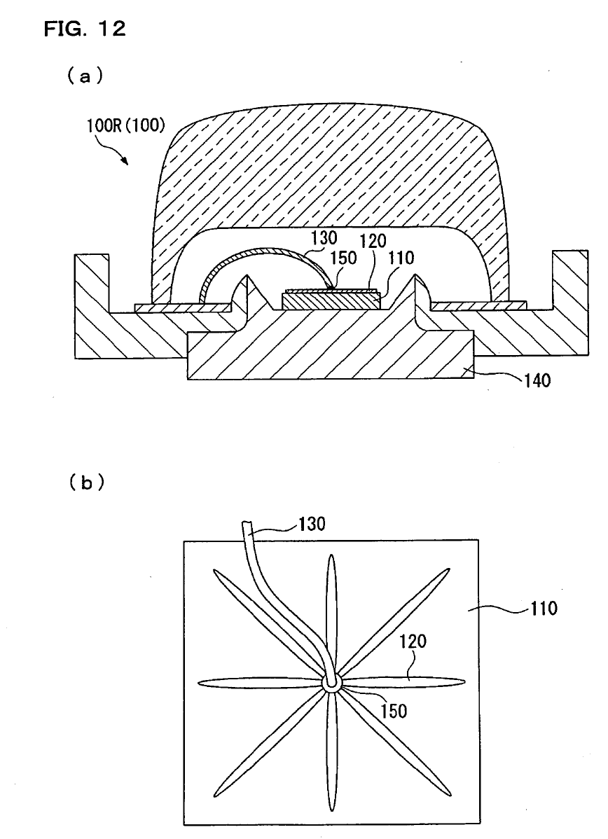

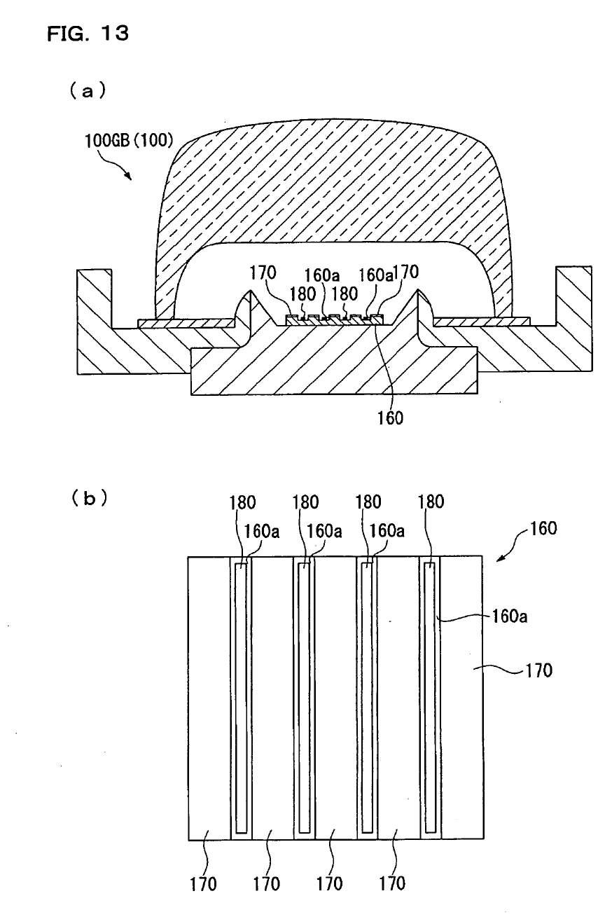

Next, a light-emitting element 41 (41R, 41G, 41B) having a different structure from the first exemplary embodiment is described with reference to FIG. 10 and FIG. 11. The different part between the light-emitting element 41 according to the second embodiment and the light-emitting element 1 according to the first exemplary embodiment is a point that reflection mirrors 42, 43 are provided instead of the optical-path change lenses 14, 36 shown in the first exemplary embodiment. In the second exemplary embodiment, only the part different from the first exemplary embodiment is described.

As shown in FIG. 10, in the red light-emitting element 41R according to the second exemplary embodiment, the reflection mirrors 42 are placed on the electrodes 16. The reflection mirrors 42 are placed obliquely such that obliquely-ejected emission light is reflected vertically to the ejection face of the chip 12 above the electrodes 16.

The reflection mirrors 42 are preferably formed using the same material as the electrodes 16. In this way, when the reflection mirrors 42 and the electrodes 16 are integrally formed, side faces of the electrodes 16 are sloped in forming the electrodes, thereby the reflection mirrors 42 can be easily formed.

According to such a red light-emitting element 41R according to the second exemplary embodiment, since the obliquely-ejected emission light is reflected vertically to the ejection face above the electrodes 16 by the reflection mirrors 42, the electrodes 16 can be visually masked.

As shown in FIG. 11, in the green and blue light-emitting elements 41G, 41B according to the second exemplary embodiment, the reflection mirrors 43 are placed on the bottoms of the grooves 31d. The reflection mirrors 43 are placed obliquely such that the obliquely-ejected emission light is reflected vertically to the ejection face above the grooves 31d. The reflection mirrors 43 are preferably formed using the same material as the electrodes 32, like the reflection mirrors 42 of the red light-emitting element 41R.

According to such green and blue light-emitting elements 41G, 41B according to the second exemplary embodiment, since the obliquely-ejected emission light is reflected vertically to the ejection face above the grooves 31d by the reflection mirrors 43, the grooves 31d can be visually masked.

Hereinbefore, while preferred exemplary embodiments of the solid state light-emitting element and the projector according to the invention have been described with reference to the appended drawings, it should be understood that the invention is not limited to the above exemplary embodiments. Various shapes or combinations of respective components shown in the described embodiments are merely examples, and various changes may be made depending on design requirement or the like without departing from the scope of the invention.

1. A solid state light-emitting element, comprising:
a solid state light-emitting element chip that emits light in electric current injection; and
electrodes that inject the electric current into the solid state light-emitting element chip, the electrodes being disposed on an ejection face of the solid state light-emitting element chip;
an optical-path change device that visually masks electrode forming areas in which the electrodes are formed on the ejection face of the solid state light-emitting element chip.

2. The solid state light-emitting element according to claim 1, an optical-path change device changing an optical path by refraction.

3. The solid state light-emitting element according to claim 1, the optical-path change device being formed using a translucent material having roots corresponding to the electrode forming areas.

4. The solid state light-emitting element according to claim 3, the translucent material being resin.

5. The solid state light-emitting element according to claim 1, the optical-path change device changing an optical path by reflection.

6. The solid state light-emitting element according to claim 5, the optical-path change device being reflection mirrors formed on the electrodes.

7. The solid state light-emitting element according to claim 6, the reflection mirrors and the electrodes being integrally formed using a same material.

8. A projector having the solid state light-emitting element according to claim 1 as a light source.

9. A method for producing a solid state light-emitting element having a solid state light-emitting element chip that emits light in electric current injection, and electrodes that inject the electric current into the solid state light-emitting element chip, the electrodes being disposed on an ejection face of the solid state light-emitting element chip, comprising:
making electrode forming areas in which the electrodes are formed to be liquid-repellent;
placing liquid resin on the ejection face of the solid state light-emitting element chip; and
hardening the liquid resin.

10. The method for producing the solid state light-emitting element according to claim 9, the liquid resin being placed by a droplet discharge technique.
